(19) United States
(12) Patent Application Publication
(10) Pub. No.: US 2022/0165313 A1
(43) Pub. Date: May 26, 2022

(54) ELECTRONIC DEVICE FOR PERFORMING DATA BUS INVERSION OPERATION

(71) Applicant: SK hynix Inc., Icheon-si (KR)

(72) Inventor: In Sung KOH, Icheon-si (KR)

(73) Assignee: SK hynix Inc., Icheon-si (KR)

(21) Appl. No.: 17/197,835

(22) Filed: Mar. 10, 2021

(30) Foreign Application Priority Data
Nov. 24, 2020 (KR) 10-2020-0159350

(51) Int. Cl. G11C 7/10; H03K 19/1776

(52) U.S. Cl. CPC G11C 7/1006; H03K 19/1776; G11C 7/1063; G11C 7/109; G11C 7/1057; G11C 7/1084

(57) ABSTRACT

An electronic device includes a first data processing circuit configured to detect logic levels of bits that are included in first data, and generate first internal data by inverting the logic levels of the first data when the number of bits in the first data that have a predetermined logic level is equal to or greater than a preset number; and a second data processing circuit configured to detect logic levels of bits that are included in second data, and generate second internal data by inverting the logic levels of the second data when the number of bits in the second data that have the predetermined logic level is equal to or greater than the preset number.

### CROSS-REFERENCE TO RELATED APPLICATION

The present application claims priority under 35 U.S.C. § 119(a) to Korean Patent Application No. 10-2020-0159350 filed on Nov. 24, 2020 in the Korean Intellectual Property Office, which is incorporated herein by reference in its entirety.

### BACKGROUND

### 1. Technical Field

Embodiments of the disclosure generally relate to an electronic device which performs a data bus inversion operation when the number of bits in data that have a predetermined logic level is equal to or greater than a preset number.

### 2. Related Art

In an electronic device including a semiconductor device, as the number of bits whose phase is changed compared to a previous time, among data bits transmitted from a controller, increases, the occurrence of a simultaneous switching noise (SSN) phenomenon and an inter-symbol interference (ISI) phenomenon increases. Therefore, when a lot of bits whose phase is changed compared to a previous time, among bits of data transmitted, are included, the semiconductor device reduces the occurrence of the SSN phenomenon and the ISI phenomenon by using a data bus inversion (DBI) operation of inverting the data and transmitting inverted data.

### SUMMARY

In an embodiment, an electronic device may include: a first data processing circuit configured to detect logic levels of bits that are included in a first data and generate a first internal data by inverting the logic levels of the first data when a number of bits in the first data that have a predetermined logic level is equal to or greater than a preset number; and a second data processing circuit configured to detect logic levels of bits that are included in a second data and generate a second internal data by inverting the logic levels of the second data when the number of bits in the second data that have the predetermined logic level is equal to or greater than the preset number.

In an embodiment, an electronic device may include: a control circuit positioned in a peripheral region, and configured to generate a data inversion enable signal that is enabled to control a data bus inversion operation on data and an internal data in a write operation and a read operation; and a data processing circuit, positioned in a memory region, configured to store the internal data that is generated by inverting or non-inverting logic levels of the data based on a result of detecting the number of bits in the data input from an exterior that have a predetermined logic level when the data inversion enable signal is enabled in the write operation, configured to generate the data by inverting or non-inverting logic levels of the internal data based on a result of detecting the number of bits in the internal data that is stored in an interior that have the predetermined logic level when the data inversion enable signal is enabled in the read operation, and configured to output the data to the exterior.

In an embodiment, an electronic device may include: a controller configured to output a first data through a first transmission line, and output a second data through a second transmission line; and a semiconductor device configured to store a first internal data that is generated by inverting logic levels of the first data when the number of bits in the first data that have a predetermined logic level is equal to or greater than a preset number, and store a second internal data that is generated by inverting logic levels of the second data when the number of bits in the second data that have the predetermined logic level is equal to or greater than a preset number.

### BRIEF DESCRIPTION OF THE DRAWINGS

FIG. 1 is a block diagram illustrating the configuration of an electronic device in accordance with an embodiment of the disclosure.

FIG. 2 is a block diagram illustrating the configuration of a semiconductor device included in the electronic device illustrated in FIG. 1.

FIG. 3 is a block diagram illustrating the configuration of a first data processing circuit included in the semiconductor device illustrated in FIG. 2.

FIG. 4 is a block diagram illustrating the configuration of a data detection circuit included in the first data processing circuit illustrated in FIG. 3.

FIG. 5 is a block diagram illustrating the configuration of a first detection circuit included in the data detection circuit illustrated in FIG. 4.

FIG. 6 is a circuit diagram illustrating the configuration of a first counter included in the first detection circuit illustrated in FIG. 5.

FIG. 7 is a block diagram illustrating the configuration of a pre-detection signal generation circuit included in the first detection circuit illustrated in FIG. 5.

FIG. 8 is a circuit diagram illustrating the configuration of a first adder included in the pre-detection signal generation circuit illustrated in FIG. 7.

FIG. 9 is a block diagram illustrating the configuration of a detection signal generation circuit included in the data detection circuit illustrated in FIG. 4.

FIG. 10 is a circuit diagram illustrating the configuration of a first synthesis circuit included in the detection signal generation circuit illustrated in FIG. 9.

FIG. 11 is a block diagram illustrating the configuration of a data transformation circuit included in the first data processing circuit illustrated in FIG. 3.

FIG. 12 is a circuit diagram illustrating the configuration of a write transformation circuit included in the data transformation circuit illustrated in FIG. 11.

FIG. 13 is a circuit diagram illustrating the configuration of a read transformation circuit included in the data transformation circuit illustrated in FIG. 11.

FIGS. 14 and 15 are diagrams to assist in the explanation of the operation of the electronic device in accordance with the embodiment of the disclosure.

FIG. 16 is a diagram illustrating the configuration of an electronic system in accordance with an embodiment of the disclosure to which the electronic device, illustrated in FIGS. 1 to 15, is applied.

### DETAILED DESCRIPTION

The terms “preset” and “predetermined” mean that the numerical value of a parameter is predetermined when the parameter is used in a process or algorithm. Depending on an embodiment, the numerical value of a parameter may be set when a process or algorithm starts or may be set during a period in which the process or algorithm is executed.

Terms such as “first” and “second” used to distinguish various components are not limited by components. For example, a first component may be named as a second component, and conversely, the second component may be named as the first component.

When it is described that one component is “coupled” or “connected” to another component, it is to be understood that the one component may be coupled or connected to the another component directly or by the medium of still another component. On the other hand, the descriptions of “directly coupled” or “directly connected” should be understood to mean that one component is coupled or connected to another component directly without intervention of a still another component.

“Logic high level” and “logic low level” are used to describe logic levels of signals. A signal with a “logic high level” is distinguished from a signal with a “logic low level.” For example, when a signal with a first voltage corresponds to a “logic high level,” a signal with a second voltage may correspond to a “logic low level.” Depending on the embodiment, a “logic high level” may be set to a voltage higher than a “logic low level.” Meanwhile, depending on the embodiment, logic levels of signals may be set to different logic levels or opposite logic levels. For example, depending on the embodiment, a signal with a logic high level may be set to have a logic low level, and a signal with a logic low level may be set to have a logic high level.

Hereinafter, various examples of embodiments of the disclosure will be described in detail with reference to the accompanying drawings. These embodiments are only for illustrating the disclosure, and the scope of protection of the disclosure is not limited by these embodiments.

Various embodiments are directed to an electronic device which includes a circuit for detecting a bit with a predetermined logic level, included in data, in order to perform a data bus inversion operation, not on an external transmission line but inside a memory region.

According to the embodiments of the disclosure, a semiconductor device may internally perform a data bus inversion operation without the control of a controller.

In addition, according to the embodiments of the disclosure, a circuit for detecting a bit with a predetermined logic level, included in data, in order to perform a data bus inversion operation is disposed not on an external transmission line but inside a memory region. Thus, the number of transmission lines may be reduced, and current consumption and area may be reduced.

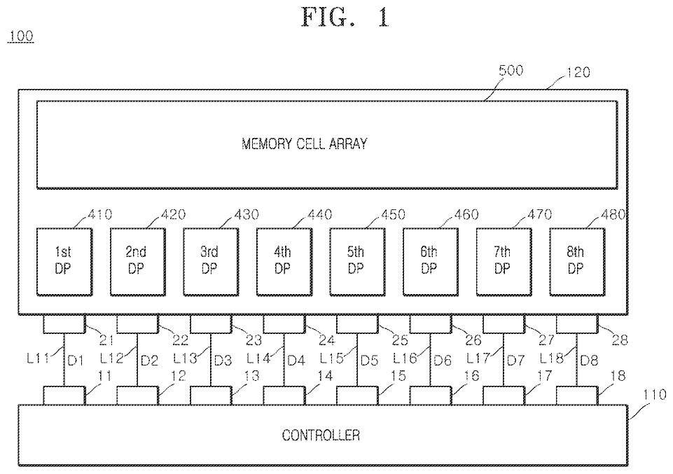

As illustrated in FIG. 1, an electronic device 100 in accordance with an embodiment of the disclosure may include a controller 110 and a semiconductor device 120. The semiconductor device 120 may include a first data processing circuit 410, a second data processing circuit 420, a third data processing circuit 430, a fourth data processing circuit 440, a fifth data processing circuit 450, a sixth data processing circuit 460, a seventh data processing circuit 470, an eighth data processing circuit 480, and a memory cell array 500.

The controller 110 may include a first control pin 11, a second control pin 12, a third control pin 13, a fourth control pin 14, a fifth control pin 15, a sixth control pin 16, a seventh control pin 17, and an eighth control pin 18. The semiconductor device 120 may include a first semiconductor pin 21, a second semiconductor pin 22, a third semiconductor pin 23, a fourth semiconductor pin 24, a fifth semiconductor pin 25, a sixth semiconductor pin 26, a seventh semiconductor pin 27, and an eighth semiconductor pin 28.

A first transmission line L11 may be coupled between the first control pin 11 and the first semiconductor pin 21. A second transmission line L12 may be coupled between the second control pin 12 and the second semiconductor pin 22. A third transmission line L13 may be coupled between the third control pin 13 and the third semiconductor pin 23. A fourth transmission line L14 may be coupled between the fourth control pin 14 and the fourth semiconductor pin 24. A fifth transmission line L15 may be coupled between the fifth control pin 15 and the fifth semiconductor pin 25. A sixth transmission line L16 may be coupled between the sixth control pin 16 and the sixth semiconductor pin 26. A seventh transmission line L17 may be coupled between the seventh control pin 17 and the seventh semiconductor pin 27. An eighth transmission line L18 may be coupled between the eighth control pin 18 and the eighth semiconductor pin 28.

The controller 110 and the semiconductor device 120 may input and output a first data D1 through the first transmission line L11. The controller 110 and the semiconductor device 120 may input and output a second data D2 through the second transmission line L12. The controller 110 and the semiconductor device 120 may input and output a third data D3 through the third transmission line L13. The controller 110 and the semiconductor device 120 may input and output a fourth data D4 through the fourth transmission line L14. The controller 110 and the semiconductor device 120 may input and output a fifth data D5 through the fifth transmission line L15. The controller 110 and the semiconductor device 120 may input and output a sixth data D6 through the sixth transmission line L16. The controller 110 and the semiconductor device 120 may input and output a seventh data D7 through the seventh transmission line L17. The controller 110 and the semiconductor device 120 may input and output an eighth data D8 through the eighth transmission line L18. According to an embodiment, each of the first to eighth data D1 to D8 may be set as a signal that includes various numbers of bits. FIG. 1 illustrates that the controller 110 and the semiconductor device 120 are input and output data through eight transmission lines. However, according to an embodiment, the controller 110 and the semiconductor device 120 may be implemented to include various number of transmission lines to input and output a command, an address, and various signals for controlling the operation of the semiconductor device 120.

In a write operation, the controller 110 may output the first to eighth data D1 to D8 through the first to eighth transmission lines L11 to L18. In the write operation, the semiconductor device 120 may receive the first to eighth data D1 to D8 that are transmitted through the first to eighth transmission lines L11 to L18. In a read operation, the semiconductor device 120 may output the first to eighth data D1 to D8 through the first to eighth transmission lines L11 to L18. In the read operation, the controller 110 may receive the first to eighth data D1 to D8 that are transmitted through the first to eighth transmission lines L11 to L18.

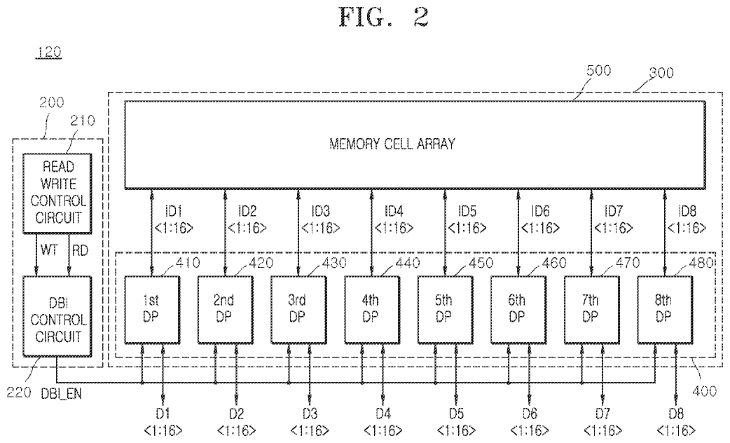

In the write operation, the first data processing circuit 410 may generate a first internal data ID1<1:16> (see FIG. 2) by inverting or non-inverting the logic levels of the first data D1 based on a result of detecting the number of bits in the first data D1 that have a predetermined logic level. In the read operation, the first data processing circuit 410 may output, to the first transmission line L11, the first data D1 that is generated by inverting or non-inverting logic levels of the first internal data ID1<1:16> (see FIG. 2) based on a result of detecting the number of bits in the first internal data ID1<1:16> that have the predetermined logic level.

In the write operation, the second data processing circuit 420 may generate a second internal data ID2<1:16> (see FIG. 2) by inverting or non-inverting logic levels of the second data D2 based on a result of detecting the number of bits in the second data D2 that have the predetermined logic level. In the read operation, the second data processing circuit 420 may output, to the second transmission line L12, the second data D2 that is generated by inverting or non-inverting logic levels of the second internal data ID2<1:16> (see FIG. 2) based on a result of detecting the number of bits in the second internal data ID2<1:16> that have the predetermined logic level.

In the write operation, the third data processing circuit 430 may generate third internal data ID3<1:16> (see FIG. 2) by inverting or non-inverting logic levels of the third data D3 based on a result of detecting the number of bits in the third data D3 that have the predetermined logic level. In the read operation, the third data processing circuit 430 may output, to the third transmission line L13, the third data D3 that is generated by inverting or non-inverting logic levels of third internal data ID3<1:16> (see FIG. 2) based on a result of detecting the number of bits in the third internal data ID3<1:16> that have the predetermined logic level.

In the write operation, the fourth data processing circuit 440 may generate fourth internal data ID4<1:16> (see FIG. 2) by inverting or non-inverting logic levels of the fourth data D4 based on a result of detecting the number of bits in the fourth data D4 that have the predetermined logic level. In the read operation, the fourth data processing circuit 440 may output, to the fourth transmission line L14, the fourth data D4 that is generated by inverting or non-inverting logic levels of fourth internal data ID4<1:16> (see FIG. 2) based on a result of detecting the number of bits in the fourth internal data ID4<1:16> that have the predetermined logic level.

In the write operation, the fifth data processing circuit 450 may generate fifth internal data ID5<1:16> (see FIG. 2) by inverting or non-inverting logic levels of the fifth data D5 based on a result of detecting the number of bits in the fifth data D5 that have the predetermined logic level. In the read operation, the fifth data processing circuit 450 may output, to the fifth transmission line L15, the fifth data D5 that is generated by inverting or non-inverting logic levels of fifth internal data ID5<1:16> (see FIG. 2) based on a result of detecting the number of bits in the fifth internal data ID5<1:16> that have the predetermined logic level.

In the write operation, the sixth data processing circuit 460 may generate sixth internal data ID6<1:16> (see FIG. 2) by inverting or non-inverting logic levels of the sixth data D6 based on a result of detecting the number of bits in the sixth data D6 that have the predetermined logic level. In the read operation, the sixth data processing circuit 460 may output, to the sixth transmission line L16, the sixth data D6 that is generated by inverting or non-inverting logic levels of sixth internal data ID6<1:16> (see FIG. 2) based on a result of detecting the number of bits in the sixth internal data ID6<1:16> that have the predetermined logic level.

In the write operation, the seventh data processing circuit 470 may generate seventh internal data ID7<1:16> (see FIG. 2) by inverting or non-inverting logic levels of the seventh data D7 based on a result of detecting the number of bits in the seventh data D7 that have the predetermined logic level. In the read operation, the seventh data processing circuit 470 may output, to the seventh transmission line L17, the seventh data D7 that is generated by inverting or non-inverting logic levels of seventh internal data ID7<1:16> (see FIG. 2) based on a result of detecting the number of bits in the seventh internal data ID7<1:16> that have the predetermined logic level.

In the write operation, the eighth data processing circuit 480 may generate eighth internal data ID8<1:16> (see FIG. 2) by inverting or non-inverting logic levels of the eighth data D8 based on a result of detecting the number of bits in the eighth data D8 that have the predetermined logic level. In the read operation, the eighth data processing circuit 480 may output, to the eighth transmission line L18, the eighth data D8 generated by inverting or non-inverting logic levels of eighth internal data ID8<1:16> (see FIG. 2) based on a result of detecting the number of bits in the eighth internal data ID8<1:16> that have the predetermined logic level.

In the write operation, the memory cell array 500 may store the first to eighth internal data ID1<1:16> to ID8<1:16> (see FIG. 2). In the read operation, the memory cell array 500 may output the first to eighth internal data ID1<1:16> to ID8<1:16> (see FIG. 2) that are stored therein.

FIG. 2 is a block diagram illustrating the configuration of the semiconductor device 120 in accordance with the embodiment of the disclosure. As illustrated in FIG. 2, the semiconductor device 120 may include a peripheral region 200 and a memory region 300.

The peripheral region 200 may include a read write control circuit 210 and a data inversion control circuit 220.

The read write control circuit 210 may generate a write signal WT that is enabled to perform the write operation under the control of the controller 110. The read write control circuit 210 may generate a read signal RD that is enabled to perform the read operation under the control of the controller 110. Logic levels of the write signal WT and the read signal RD that are enabled to perform the write operation and the read operation may be set to a logic high level or a logic low level according to an embodiment.

The data inversion control circuit 220 may generate a data inversion enable signal DBI_EN that is enabled to perform a data bus inversion operation when any one of the write signal WT and the read signal RD is enabled. The logic level of the data inversion enable signal DBI_EN that is enabled to perform the data bus inversion operation may be set to a logic high level or a logic low level according to an embodiment.

The memory region 300 may include a data processing circuit 400 and the memory cell array 500. The data processing circuit 400 may include the first data processing circuit 410, the second data processing circuit 420, the third data processing circuit 430, the fourth data processing circuit 440, the fifth data processing circuit 450, the sixth data processing circuit 460, the seventh data processing circuit 470 and the eighth data processing circuit 480.

In the write operation, the first data processing circuit 410 may receive the first data D1<1:16> through the first transmission line L11. In the write operation, when the data inversion enable signal DBI_EN is enabled to a logic high level, the first data processing circuit 410 may detect the number of bits in the first data D1<1:16> that have the predetermined logic level. When the number of bits in the first data D1<1:16> that have the predetermined logic level is equal to or greater than a preset number, the first data processing circuit 410 may generate the first internal data ID1<1:16> by inverting logic levels of the first data D1<1:16>. When the number of bits in the first data D1<1:16> that have the predetermined logic level is less than the preset number, the first data processing circuit 410 may generate the first internal data ID1<1:16> by non-inverting logic levels of the first data D1<1:16>. In the read operation, when the data inversion enable signal DBI_EN is enabled to a logic high level, the first data processing circuit 410 may detect the number of bits in the first internal data ID1<1:16> that have the predetermined logic level. When the number of bits in the first internal data ID1<1:16> that have the predetermined logic level is equal to or greater than the preset number, the first data processing circuit 410 may generate the first data D1<1:16> by inverting logic levels of the first internal data ID1<1:16>. When the number of bits in the first internal data ID1<1:16> that have the predetermined logic level is less than the preset number, the first data processing circuit 410 may generate the first data D1<1:16> by non-inverting logic levels of the first internal data ID1<1:16>. In the read operation, the first data processing circuit 410 may output the first data D1<1:16> through the first transmission line L11. The predetermined logic level may be set to a logic high level. The preset number may be set to 10 as the number of bits that have a logic high level.

In the write operation, the second data processing circuit 420 may receive the second data D2<1:16> through the second transmission line L12. In the write operation, when the data inversion enable signal DBI_EN is enabled to a logic high level, the second data processing circuit 420 may detect the number of bits in the second data D2<1:16> that have the predetermined logic level. When the number of bits in the second data D2<1:16> that have the predetermined logic level is equal to or greater than the preset number, the second data processing circuit 420 may generate the second internal data ID2<1:16> by inverting logic levels of the second data D2<1:16>. When the number of bits in the second data D2<1:16> that have the predetermined logic level is less than the preset number, the second data processing circuit 420 may generate the second internal data ID2<1:16> by non-inverting logic levels of the second data D2<1:16>. In the read operation, when the data inversion enable signal DBI_EN is enabled to a logic high level, the second data processing circuit 420 may detect the number of bits in the second internal data ID2<1:16> that have the predetermined logic level. When the number of bits in the second internal data ID2<1:16> that have the predetermined logic level is equal to or greater than the preset number, the second data processing circuit 420 may generate the second data D2<1:16> by inverting logic levels of the second internal data ID2<1:16>. When the number of bits in the second internal data ID2<1:16> that have the predetermined logic level is less than the preset number, the second data processing circuit 420 may generate the second data D2<1:16> by non-inverting logic levels of the second internal data ID2<1:16>. In the read operation, the second data processing circuit 420 may output the second data D2<1:16> through the second transmission line L12.

In the write operation, the third data processing circuit 430 may receive the third data D3<1:16> through the third transmission line L13. In the write operation, when the data inversion enable signal DBI_EN is enabled to a logic high level, the third data processing circuit 430 may detect the number of bits in the third data D3<1:16> that have the predetermined logic level. When the number of bits in the third data D3<1:16> that have the predetermined logic level is equal to or greater than the preset number, the third data processing circuit 430 may generate the third internal data ID3<1:16> by inverting logic levels of the third data D3<1:16>. When the number of bits in the third data D3<1:16> that have the predetermined logic level is less than the preset number the third data processing circuit 430 may generate the third internal data ID3<1:16> by non-inverting logic levels of the third data D3<1:16>, In the read operation, when the data inversion enable signal DBI_EN is enabled to a logic high level, the third data processing circuit 430 may detect the number of bits in the third internal data ID3<1:16> that have the predetermined logic level. When the number of bits in the third internal data ID3<1:16> that have the predetermined logic level is equal to or greater than the preset number, the third data processing circuit 430 may generate the third data D3<1:16> by inverting logic levels of the third internal data ID3<1:16>, When the number of bits in the third internal data ID3<1:16> that have the predetermined logic level is less than the preset number, the third data processing circuit 430 may generate the third data D3<1:16> by non-inverting logic levels of the third internal data ID3<1:16>. In the read operation, the third data processing circuit 430 may output the third data D3<1:16> through the third transmission line L13.

In the write operation, the fourth data processing circuit 440 may receive the fourth data D4<1:16> through the fourth transmission line L14. In the write operation, when the data inversion enable signal DBI_EN is enabled to a logic high level, the fourth data processing circuit 440 may detect the number of bits in the fourth data D4<1:16> that have the predetermined logic level. When the number of bits in the fourth data D4<1:16> that have the predetermined logic level is equal to or greater than the preset number, the fourth data processing circuit 440 may generate the fourth internal data ID4<1:16> by inverting logic levels of the fourth data D4<1:16>. When the number of bits in the fourth data D4<1:16> that have the predetermined logic level is less than the preset number, the fourth data processing circuit 440 may generate the fourth internal data ID4<1:16> by non-inverting logic levels of the fourth data D4<1:16>. In the read operation, when the data inversion enable signal DBI_EN is enabled to a logic high level, the fourth data processing circuit 440 may detect the number of bits in the fourth internal data ID4<1:16> that have the predetermined logic level. When the number of bits in the fourth internal data ID4<1:16> that have the predetermined logic level is equal to or greater than the preset number, the fourth data processing circuit 440 may generate the fourth data D4<1:16> by inverting logic levels of the fourth internal data ID4<1:16>. When the number of bits in the fourth internal data ID4<1:16> that have the predetermined logic level is less than the preset number, the fourth data processing circuit 440 may generate the fourth data D4<1:16> by non-inverting logic levels of the fourth internal data ID4<1:16>. In the read operation, the fourth data processing circuit 440 may output the fourth data D4<1:16> through the fourth transmission line L14.

In the write operation, the fifth data processing circuit 450 may receive the fifth data D5<1:16> through the fifth transmission line L15. In the write operation, when the data inversion enable signal DBI_EN is enabled to a logic high level, the fifth data processing circuit 450 may detect the number of bits in the fifth data D5<1:16> that have the predetermined logic level. When the number of bits in the fifth data D5<1:16> that have the predetermined logic level is equal to or greater than the preset number, the fifth data processing circuit 450 may generate the fifth internal data ID5<1:16> by inverting logic levels of the fifth data D5<1:16>. When the number of bits in the fifth data D5<1:16> that have the predetermined logic level is less than the preset number, the fifth data processing circuit 450 may generate the fifth internal data ID5<1:16> by non-inverting logic levels of the fifth data D5<1:16>. In the read operation, when the data inversion enable signal DBI_EN is enabled to a logic high level, the fifth data processing circuit 450 may detect the number of bits in the fifth internal data ID5<1:16> that have the predetermined logic level. When the number of bits in the fifth internal data ID5<1:16> that have the predetermined logic level is equal to or greater than the preset number, the fifth data processing circuit 450 may generate the fifth data D5<1:16> by inverting logic levels of the fifth internal data ID5<1:16>. When the number of bits in the fifth internal data ID5<1:16> that have the predetermined logic level is less than the preset number, the fifth data processing circuit 450 may generate the fifth data D5<1:16> by non-inverting logic levels of the fifth internal data ID5<1:16>. In the read operation, the fifth data processing circuit 450 may output the fifth data D5<1:16> through the fifth transmission line L15.

In the write operation, the sixth data processing circuit 460 may receive the sixth data D6<1:16> through the sixth transmission line L16. In the write operation, when the data inversion enable signal DBI_EN is enabled to a logic high level, the sixth data processing circuit 460 may detect the number of bits in the sixth data D6<1:16> that have the predetermined logic level. When the number of bits in the sixth data D6<1:16> that have the predetermined logic level is equal to or greater than the preset number, the sixth data processing circuit 460 may generate the sixth internal data ID6<1:16> by inverting logic levels of the sixth data D6<1:16>, When the number of bits in the sixth data D6<1:16> that have the predetermined logic level is less than the preset number, the sixth data processing circuit 460 may generate the sixth internal data ID6<1:16> by non-inverting logic levels of the sixth data D6<1:16>, In the read operation, when the data inversion enable signal DBI_EN is enabled to a logic high level, the sixth data processing circuit 460 may detect the number of bits in the sixth internal data ID6<1:16> that have the predetermined logic level. When the number of bits in the sixth internal data ID6<1:16> that have the predetermined logic level is equal to or greater than the preset number, the sixth data processing circuit 460 may generate the sixth data D6<1:16> by inverting logic levels of the sixth internal data ID6<1:16>, When the number of bits in the sixth internal data ID6<1:16> that have the predetermined logic level is less than the preset number, the sixth data processing circuit 460 may generate the sixth data D6<1:16> by non-inverting logic levels of the sixth internal data ID6<1:16>. In the read operation, the sixth data processing circuit 460 may output the sixth data D6<1:16> through the sixth transmission line L16.

In the write operation, the seventh data processing circuit 470 may receive the seventh data D7<1:16> through the seventh transmission line L17. In the write operation, when the data inversion enable signal DBI_EN is enabled to a logic high level, the seventh data processing circuit 470 may detect the number of bits in the seventh data D7<1:16> that have the predetermined logic level. When the number of bits in the seventh data D7<1:16> that have the predetermined logic level is equal to or greater than the preset number, the seventh data processing circuit 470 may generate the seventh internal data ID7<1:16> by inverting logic levels of the seventh data D7<1:16>. When the number of bits in the seventh data D7<1:16> that have the predetermined logic level is less than the preset number, the seventh data processing circuit 470 may generate the seventh internal data ID7<1:16> by non-inverting logic levels of the seventh data D7<1:16>. In the read operation, when the data inversion enable signal DBI_EN is enabled to a logic high level, the seventh data processing circuit 470 may detect the number of bits in the seventh internal data ID7<1:16> that have the predetermined logic level. When the number of bits in the seventh internal data ID7<1:16> that have the predetermined logic level is equal to or greater than the preset number, the seventh data processing circuit 470 may generate the seventh data D7<1:16> by inverting logic levels of the seventh internal data ID7<1:16>. When the number of bits in the seventh internal data ID7<1:16> that have the predetermined logic level is less than the preset number, the seventh data processing circuit 470 may generate the seventh data D7<1:16> by non-inverting logic levels of the seventh internal data ID7<1:16>. In the read operation, the seventh data processing circuit 470 may output the seventh data D7<1:16> through the seventh transmission line L17.

In the write operation, the eighth data processing circuit 480 may receive the eighth data D8<1:16> through the eighth transmission line L18. In the write operation, when the data Inversion enable signal DBI_EN is enabled to a logic high level, the eighth data processing circuit 480 may detect the number of bits in the eighth data D8<1:16> that have the predetermined logic level. When the number of bits in the eighth data D8<1:16> that have the predetermined logic level is equal to or greater than the preset number, the eighth data processing circuit 480 may generate the eighth internal data ID8<1:16> by inverting logic levels of the eighth data D8<1:16>. When the number of bits in the eighth data D8<1:16> that have the predetermined logic level is less than the preset number, the eighth data processing circuit 480 may generate the eighth internal data ID8<1:16> by non-inverting logic levels of the eighth data D8<1:16>. In the read operation, when the data inversion enable signal DBI_EN is enabled to a logic high level, the eighth data processing circuit 480 may detect the number of bits in the eighth internal data ID8<1:16> that have the predetermined logic level. When the number of bits in the eighth internal data ID8<1:16> that have the predetermined logic level is equal to or greater than the preset number, the eighth data processing circuit 480 may generate the eighth data D8<1:16> by inverting logic levels of the eighth internal data ID8<1:16>. When the number of bits in the eighth internal data ID8<1:16> that have the predetermined logic level is less than the preset number, the eighth data processing circuit 480 may generate the eighth data D8<1:16> by non-inverting logic levels of the eighth internal data ID8<1:16>. In the read operation, the eighth data processing circuit 480 may output the eighth data D8<1:16> through the eighth transmission line L18.

In the write operation, the memory cell array 500 may store the first to eighth internal data ID1<1:16> to ID8<1:16> output from the data processing circuit 400. In the read operation, the memory cell array 500 may output the first to eighth internal data ID1<1:16> to ID8<1:16>, stored therein, to the data processing circuit 400.

The data processing circuit 400 illustrated in FIG. 2 is implemented to include the first to eighth data processing circuits 410 to 480, but may be implemented to include various numbers of data processing circuits according to an embodiment.

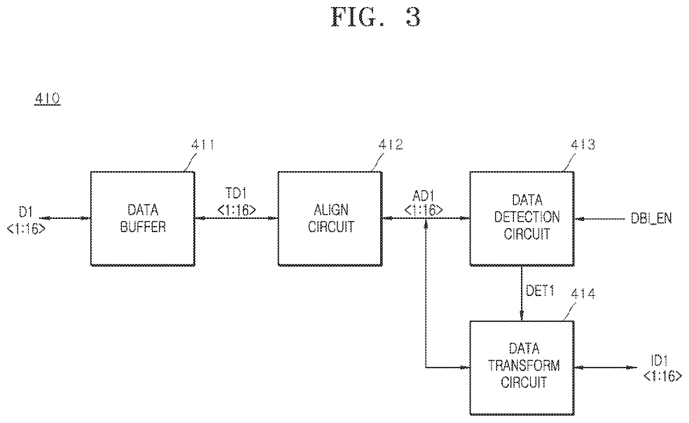

As illustrated in FIG. 3, the first data processing circuit 410 may include a data buffer 411, an alignment circuit 412, a data detection circuit 413 and a data transformation circuit 414.

In the write operation, the data buffer 411 may receive the first data D1<1:16> and generate a first transfer data TD1<1:16>, In the write operation, the data buffer 411 may generate the first transfer data TD1<1:16> by buffering the first data D1<1:16>. In the read operation, the data buffer 411 may receive first transfer data TD1<1:16> and generate the first data D1<1:16>. In the read operation, the data buffer 411 may generate the first data D1<1:16> by buffering the first transfer data TD1<1:16>.

In the write operation, the alignment circuit 412 may generate a first alignment data AD1<1:16> by aligning and parallelizing the first transfer data TD1<1:16> input in series. In the read operation, the alignment circuit 412 may generate the first transfer data TD1<1:16> by aligning and serializing the first alignment data AD1<1:16> that is input in parallel.

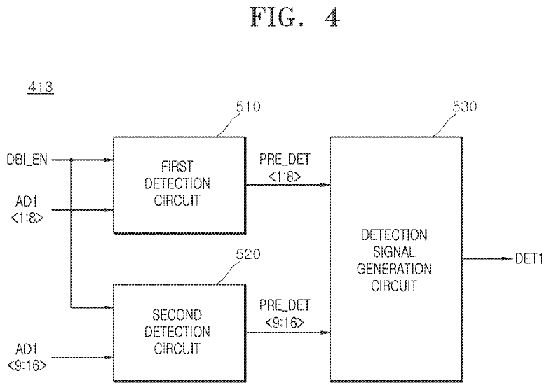

In the write operation and the red operation, the data detection circuit 413 may generate a first detection signal DET1 by detecting the number of bits in the first alignment data AD1<1:16> that have the predetermined logic level. The data detection circuit 413 may generate the first detection signal DET1 that is enabled when the number of bits in the first alignment data AD1<1:16> that have the predetermined logic level is equal to or greater than the preset number in the case where the data inversion enable signal DBI_EN is enabled. The data detection circuit 413 may generate the first detection signal DET1 that is enabled when the data inversion enable signal DBI_EN is enabled and the number of bits in the first alignment data AD1<1:16> that have a logic high level, is equal to or greater than 10. The operation in which the data detection circuit 413 may generate the first detection signal DET1 will be described in detail with reference to FIGS. 4 to 9 to be described later.

In the write operation, the data transformation circuit 414 may generate the first internal data ID1<1:16> by inverting or non-inverting the first alignment data AD1<1:16> based on the first detection signal DET1. In the write operation, the data transformation circuit 414 may generate the first internal data ID1<1:16> by inverting the first alignment data AD1<1:16> when the first detection signal DET1 is enabled. In the write operation, the data transformation circuit 414 may generate the first internal data ID1<1:16> by non-inverting the first alignment data AD1<1:16> when the first detection signal DET1 is disabled. In the read operation, the data transformation circuit 414 may generate the first alignment data AD1<1:16> by inverting or non-inverting the first internal data ID1<1:16> based on the first detection signal DET1. In the read operation, the data transformation circuit 414 may generate the first alignment data AD1<1:16> by inverting the first internal data ID1<1:16> when the first detection signal DET1 is enabled. In the read operation, the data transformation circuit 414 may generate the first alignment data AD1<1:16> by non-inverting the first internal data ID1<1:16> when the first detection signal DET1 is disabled. In the read operation, the data transformation circuit 414 may output the first alignment data AD1<1:16> by non-inverting the first internal data ID1<1:16>, and thereafter, may generate the first alignment data AD1<1:16> by inverting or non-inverting the first internal data ID1<1:16> based on the first detection signal DET1.

Meanwhile, since each of the second to eighth data processing circuits 420 to 480 illustrated in FIG. 2 is implemented by the same circuits and perform the same operation as the first data processing circuit 410 except that input and output signals thereof are different from those of the first data processing circuit 410, detailed descriptions thereof will be omitted.

As illustrated in FIG. 4, the data detection circuit 413 may include a first detection circuit 510, a second detection circuit 520 and a detection signal generation circuit 530.

When the data inversion enable signal DBI_EN is enabled, the first detection circuit 510 may generate a first group PRE_DET<1:8> of a first pre-detection signal by detecting logic levels of a first group of bits AD1<1:8> included in the first alignment data AD1<1:16>. When the data inversion enable signal DBI_EN is enabled, the first detection circuit 510 may generate the first group PRE_DET<1:8> of the first pre-detection signal with information on the number of bits in the first alignment data AD1<1:16> that have the predetermined logic level.

When the data inversion enable signal DBI_EN is enabled, the second detection circuit 520 may generate a second group PRE_DET<9:16> of the first pre-detection signal by detecting logic levels of a second group of bits AD1<9:16> included in the first alignment data AD1<1:16>. When the data inversion enable signal DBI_EN is enabled, the second detection circuit 520 may generate the second group PRE_DET<9:16> of the first pre-detection signal with information on the number of bits in the first alignment data AD1<1:16> that have the predetermined logic level.

The detection signal generation circuit 530 may generate the first detection signal DET1 by detecting logic levels of the first group PRE_DET<1:8> of the first pre-detection signal and the second group PRE_DET<9:16> of the first pre-detection signal. The detection signal generation circuit 530 may generate the first detection signal DET1 based on a logic level combination of the first group PRE_DET<1:8> of the first pre-detection signal and the second group PRE_DET<9:16> of the first pre-detection signal.

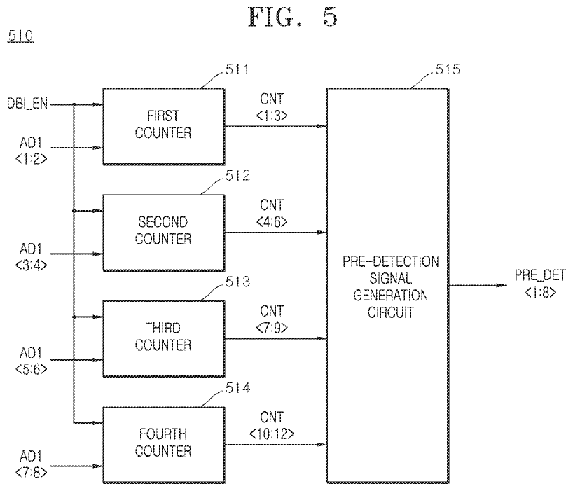

As illustrated in FIG. 5, the first detection circuit 510 may include a first counter 511, a second counter 512, a third counter 513, a fourth counter 514 and a pre-detection signal generation circuit 515.

The first counter 511 may generate first to third counting signals CNT<1:3> by detecting logic levels of first and second bits AD1<1:2> of the first alignment data AD1<1:16> when the data inversion enable signal DBI_EN is enabled. The first counter 511 may generate the first to third counting signals CNT<1:3> by detecting the number of bits that have a logic high level between the first and second bits AD1<1:2> of the first alignment data AD1<1:16>, when the data inversion enable signal DBI_EN is enabled. The first counter 511 may generate the first to third counting signals CNT<1:3> that are selectively enabled based on the number of bits that have a logic high level between the first and second bits AD1<1:2> of the first alignment data AD1<1:16>, when the data inversion enable signal DBI_EN is enabled.

The second counter 512 may generate fourth to sixth counting signals CNT<4:6> by detecting logic levels of third and fourth bits AD1<3:4> of the first alignment data AD1<1:16> when the data inversion enable signal DBI_EN is enabled. The second counter 512 may generate the fourth to sixth counting signals CNT<4:6> by detecting the number of bits that have a logic high level between the third and fourth bits AD1<3:4> of the first alignment data AD1<1:16>, when the data inversion enable signal DBI_EN is enabled. The second counter 512 may generate the fourth to sixth counting signals CNT<4:6> that are selectively enabled based on the number of bits that have a logic high level between the third and fourth bits AD1<3:4> of the first alignment data AD1<1:16>, when the data inversion enable signal DBI_EN is enabled.

The third counter 513 may generate seventh to ninth counting signals CNT<7:9> by detecting logic levels of fifth and sixth bits AD1<5:6> of the first alignment data AD1<1:16> when the data inversion enable signal DBI_EN is enabled. The third counter 513 may generate the seventh to ninth counting signals CNT<7:9> by detecting the number of bits that have a logic high level between the fifth and sixth bits AD1<5:6> of the first alignment data AD1<1:16>, when the data inversion enable signal DBI_EN is enabled. The third counter 513 may generate the seventh to ninth counting signals CNT<7:9> that are selectively enabled based on the number of bits that have a logic high level between the fifth and sixth bits AD1<5:6> of the first alignment data AD1<1:16>, when the data inversion enable signal DBI_EN is enabled.

The fourth counter 514 may generate tenth to twelfth counting signals CNT<10:12> by detecting logic levels of seventh and eighth bits AD1<7:8> of the first alignment data AD1<1:16> when the data inversion enable signal DBI_EN is enabled. The fourth counter 514 may generate the tenth to twelfth counting signals CNT<10:12> by detecting the number of bits that have a logic high level between the seventh and eighth bits AD1<7:8> of the first alignment data AD1<1:16>, when the data inversion enable signal DBI_EN is enabled. The fourth counter 514 may generate the tenth to twelfth counting signals CNT<10:12> that are selectively enabled based on the number of bits that have a logic high level between the seventh and eighth bits AD1<7:8> of the first alignment data AD1<1:16>, when the data inversion enable signal DBI_EN is enabled.

The pre-detection signal generation circuit 515 may generate the first group PRE_DET<1:8> of the first pre-detection signal by detecting logic levels of the first to twelfth counting signals CNT<1:12>. The pre-detection signal generation circuit 515 may generate the first group PRE_DET<1:8> of the first pre-detection signal based on logic levels of the first to twelfth counting signals CNT<1:12>.

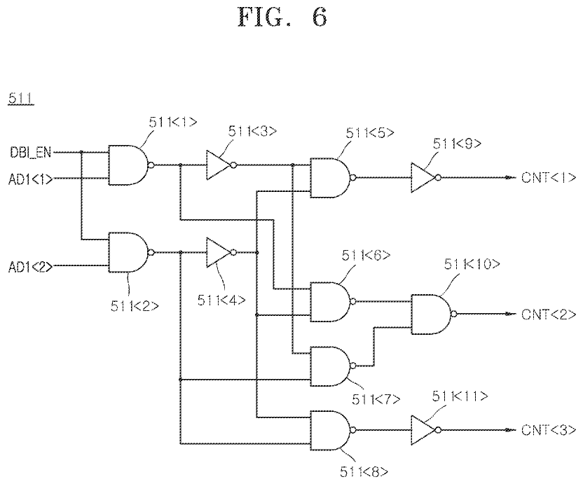

As illustrated in FIG. 6, the first counter 511 may be implemented by NAND gates 511<1>, 511<2>, 511<5>, 511<6>, 511<7>, 511<8> and 511<10> and inverters 511<3>, 511<4>, 511<9> and 511<11>.

The first counter 511 may generate the first counting signal CNT<1> that is enabled to a logic high level when the data inversion enable signal DBI_EN is enabled to a logic high level and the number of bits that have a logic high level between the first and second bits AD1<1:2> of the first alignment data AD1<1:16>, is two. The first counter 511 may generate the second counting signal CNT<2> that is enabled to a logic high level when the data inversion enable signal DBI_EN is enabled to a logic high level and the number of bits that have a logic high level between the first and second bits AD1<1:2> of the first alignment data AD1<1:16>, is one. The first counter 511 may generate the third counting signal CNT<3> that is enabled to a logic high level when the data inversion enable signal DBI_EN is enabled to a logic high level and the number of bits that have a logic high level between the first and second bits AD1<1:2> of the first alignment data AD1<1:16>, is zero. That is to say, the first counting signal CNT<1> is a signal that is enabled when the number of bits that have a logic high level between the first and second bits AD1<1:2> of the first alignment data AD1<1:16>, is two. The second counting signal CNT<2> is a signal that is enabled when the number of bits that have a logic high level between the first and second bits AD1<1:2> of the first alignment data AD1<1:16>, is one. The third counting signal CNT<3> is a signal that is enabled when the number of bits that have a logic high level between the first and second bits AD1<1:2> of the first alignment data AD1<1:16>, is zero.

Meanwhile, since each of the second counter 512, the third counter 513 and the fourth counter 514 is implemented by the same circuit and performs the same operation as the first counter 511 except that input and output signals thereof are different from those of the first counter 511, detailed description thereof will be omitted herein.

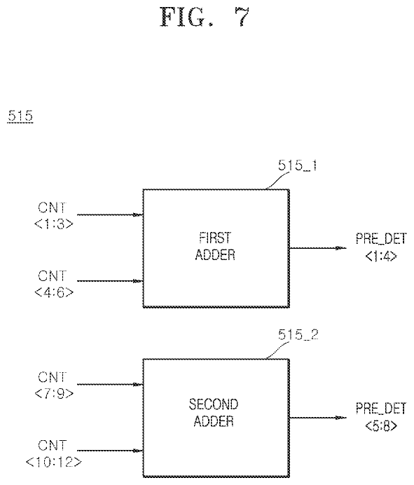

As illustrated in FIG. 7, the pre-detection signal generation circuit 515 may include a first adder 515_1 and a second adder 515_2.

The first adder 515_1 may generate first to fourth bits PRE_DET<1:4> of the first pre-detection signal that are selectively enabled based on logic levels of the first to third counting signals CNT<1:3> and the fourth to sixth counting signals CNT<4:6>.

The second adder 515_2 may generate fifth to eighth bits PRE_DET<5:8> of the first pre-detection signal that are selectively enabled based on logic levels of the seventh to ninth counting signals CNT<7:9> and the tenth to twelfth counting signals CNT<10:12>.

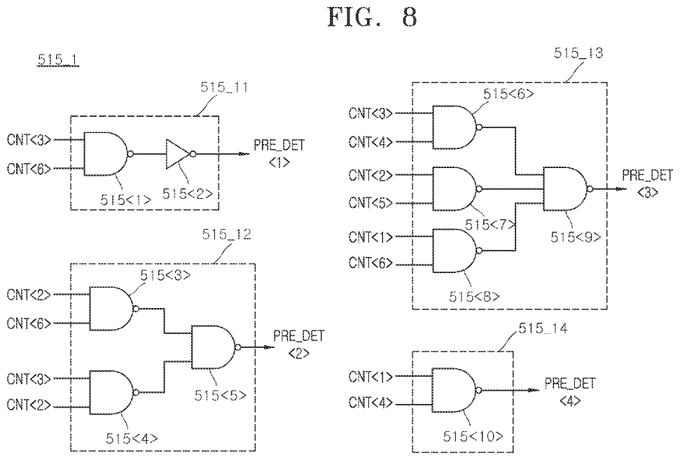

As illustrated in FIG. 8, the first adder 515_1 may include a first logic circuit 515_11, a second logic circuit 515_12, a third logic circuit 515_13 and a fourth logic circuit 515_14.

The first logic circuit 515_11 may be implemented by a NAND gate 515<1> and an inverter 515<2>. The first logic circuit 515_11 may generate the first bit PRE_DET<1> of the first pre-detection signal based on logic levels of the third counting signal CNT<3> and the sixth counting signal CNT<6>. The first bit PRE_DET<1> of the first pre-detection signal is a signal that is enabled when the number of bits that have a logic high level among the first to fourth bits AD1<1:4> of the first alignment data AD1<1:16>, is zero.

The second logic circuit 515_12 may be implemented by NAND gates 515<3>, 515<4> and 515<5>. The second logic circuit 515_12 may generate the second bit PRE_DET<2> of the first pre-detection signal based on logic levels of the second counting signal CNT<2>, the sixth counting signal CNT<6>, the third counting signal CNT<3> and the second counting signal CNT<2>. The second bit PRE_DET<2> of the first pre-detection signal is a signal that is enabled when the number of bits that have a logic high level among the first to fourth bits AD1<1:4> of the first alignment data AD1<1:16>, is one.

The third logic circuit 515_13 may be implemented by NAND gates 515<6>, 515<7>, 515<8> and 515<9>, The third logic circuit 515_13 may generate the third bit PRE_DET<3> of the first pre-detection signal based on logic levels of the third counting signal CNT<3>, the fourth counting signal CNT<4>, the second counting signal CNT<2>, the fifth counting signal CNT<5>, the first counting signal CNT<1> and the sixth counting signal CNT<6>. The third bit PRE_DET<3> of the first pre-detection signal is a signal that is enabled when the number of bits that have a logic high level among the first to fourth bits AD1<1:4> of the first alignment data AD1<1:16>, is two.

The fourth logic circuit 515_14 may be implemented by a NAND gate 515<10>. The fourth logic circuit 515_14 may generate the fourth bit PRE_DET<4> of the first pre-detection signal based on logic levels of the first counting signal CNT<1> and the fourth counting signal CNT<4>. The fourth bit PRE_DET<4> of the first pre-detection signal is a signal that is enabled when the number of bits that have a logic high level among the first to fourth bits AD1<1:4> of the first alignment data AD1<1:16>, is four.

Meanwhile, since the second adder 515_2 is implemented by the same circuit and performs the same operation as the first adder 515_1 illustrated in FIG. 8 except that input and output signals thereof are different from those of the first adder 515_1, detailed description thereof will be omitted herein.

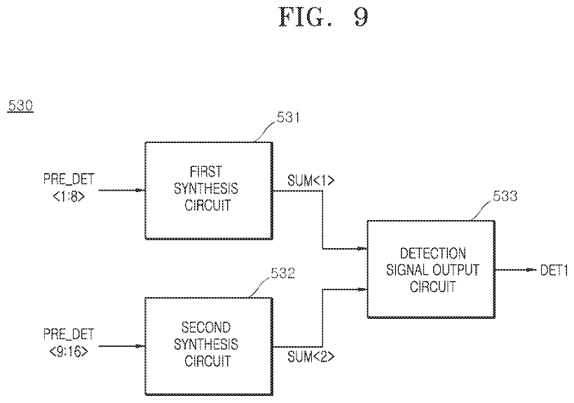

As illustrated in FIG. 9, the detection signal generation circuit 530 may include a first synthesis circuit 531, a second synthesis circuit 532 and a detection signal output circuit 533.

The first synthesis circuit 531 may generate a first synthesis signal SUM<1> based on a logic level combination of the first group PRE_DET<1:8> of the first pre-detection signal. The first synthesis circuit 531 may generate the first synthesis signal SUM<1> by synthesizing logic levels of the first group PRE_DET<1:8> of the first pre-detection signal. The first synthesis signal SUM<1> is a signal that is enabled when the number of bits that have a logic high level among the first group of bits AD1<1:8> of the first alignment data AD1<1:16>, is four.

The second synthesis circuit 532 may generate a second synthesis signal SUM<2> based on a logic level combination of the second group PRE_DET<9:16> of the first pre-detection signal. The second synthesis circuit 532 may generate the second synthesis signal SUM<2> by synthesizing logic levels of the second group PRE_DET<9:16> of the first pre-detection signal. The second synthesis signal SUM<2> is a signal that is enabled when the number of bits that have a logic high level among the second group of bits AD1<9:16> of the first alignment data AD1<1:16>, is four.

The detection signal output circuit 533 may generate the first detection signal DET1 based on a logic level combination of the first synthesis signal SUM<1> and the second synthesis signal SUM<2>. The detection signal output circuit 533 may generate the first detection signal DET1 by performing an ANDing operation on the first synthesis signal SUM<1> and the second synthesis signal SUM<2>. The detection signal output circuit 533 may generate the first detection signal DET1 that is enabled to a logic high level when both the first synthesis signal SUM<1> and the second synthesis signal SUM<2> are enabled to logic high levels.

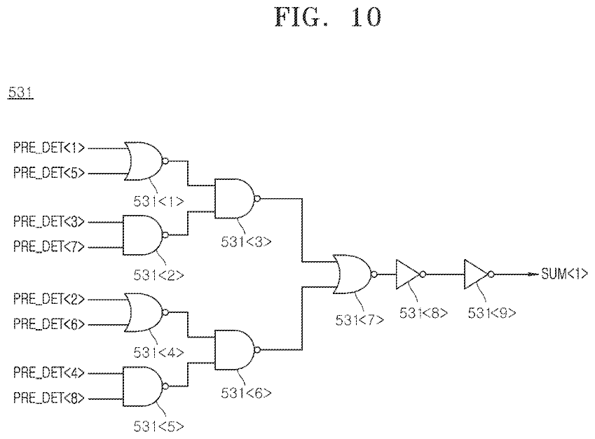

As illustrated in FIG. 10, the first synthesis circuit 531 may be implemented by NOR gates 531<1>, 531<4> and 531<7>, NAND gates 531<2>, 531<3>, 531<5> and 531<6> and inverters 531<8> and 531<9>.

The first synthesis circuit 531 may generate the first synthesis signal SUM<1> that is enabled to a logic high level when all of the first bit PRE_DET<1> and the fifth bit PRE_DET<5> of the first pre-detection signal are logic low levels, all of the second bit PRE_DET<2> and the sixth bit PRE_DET<6> of the first pre-detection signal are logic low levels and any one of the third bit PRE_DET<3>, the seventh bit PRE_DET<7>, the fourth bit PRE_DET<4> and the eighth bit PRE_DET<8> of the first pre-detection signal is a logic low level.

Meanwhile, since the second synthesis circuit 532 is implemented by same circuit and performs the same operation as the first synthesis circuit 531 illustrated in FIG. 10 except that input and output signals thereof are different from those of the first synthesis circuit 531, detailed description thereof will be omitted herein.

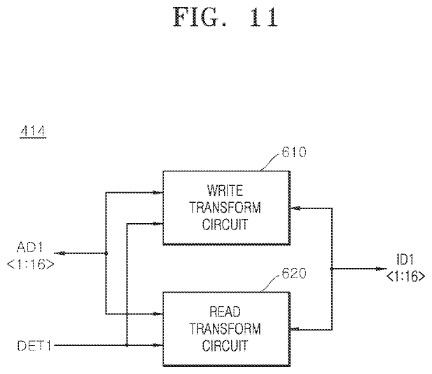

As illustrated in FIG. 11, the data transformation circuit 414 may include a write transformation circuit 610 and a read transformation circuit 620.

In the write operation, the write transformation circuit 610 may generate the first internal data ID1<1:16> by inverting or non-inverting the first alignment data AD1<1:16> based on the first detection signal DET1. In the write operation, the write transformation circuit 610 may generate the first internal data ID1<1:16> by inverting the first alignment data AD1<1:16> when the first detection signal DET1 is enabled. In the write operation, the write transformation circuit 610 may generate the first internal data ID1<1:16> by non-inverting the first alignment data AD1<1:16> when the first detection signal DET1 is disabled.

In the read operation, the read transformation circuit 620 may generate the first alignment data AD1<1:16> by inverting or non-inverting the first internal data ID1<1:16> based on the first detection signal DET1. In the read operation, the read transformation circuit 620 may generate the first alignment data AD1<1:16> by inverting the first internal data ID1<1:16> when the first detection signal DET1 is enabled. In the read operation, the read transformation circuit 620 may generate the first alignment data AD1<1:16> by non-inverting the first internal data ID1<1:16> when the first detection signal DET1 is disabled. In the read operation, the read transformation circuit 620 may output the first alignment data AD1<1:16> by non-inverting the first internal data ID1<1:16>, and thereafter, may generate the first alignment data AD1<1:16> by inverting or non-inverting the first internal data ID1<1:16> based on the first detection signal DET1.

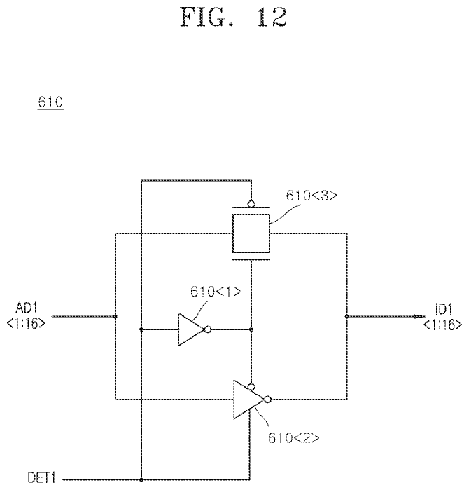

As illustrated in FIG. 12, the write transformation circuit 610 may be implemented by inverters 617<1> and 610<2> and a transfer gate 610<3>.

The inverter 610<1> may invert and buffer the first detection signal DET1, and may output an output signal.

The inverter 610<2> may be turned on when the first detection signal DET1 is enabled to a logic high level in the write operation, and thereby, may generate the first internal data ID1<1:16> by inverting the first alignment data AD1<1:16>.

The transfer gate 610<3> may be turned on when the first detection signal DET1 is disabled to a logic low level in the write operation, and thereby, may generate the first internal data ID1<1:16> by buffering the first alignment data AD1<1:16>.

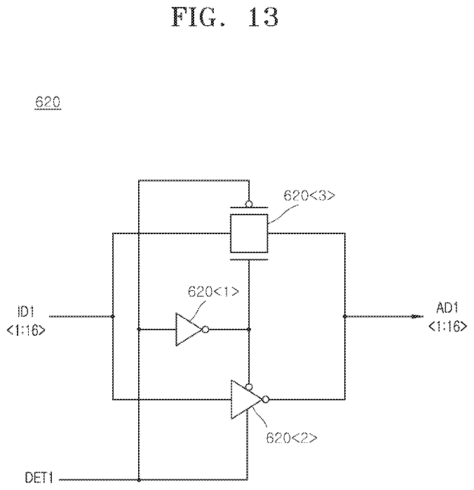

As illustrated in FIG. 13, the read transformation circuit 620 may be implemented by inverters 627<1> and 620<2> and a transfer gate 620<3>.

The inverter 620<1> may invert and buffer the first detection signal DET1, and may output an output signal.

In the read operation, the inverter 620<2> may generate the first alignment data AD1<1:16> by inverting the first internal data ID1<1:16> when the first detection signal DET1 is enabled to a logic high level.

In the read operation, the transfer gate 620<3> may generate the first alignment data AD1<1:16> by buffering the first internal data ID1<1:16> when the first detection signal DET1 is disabled to a logic low level.

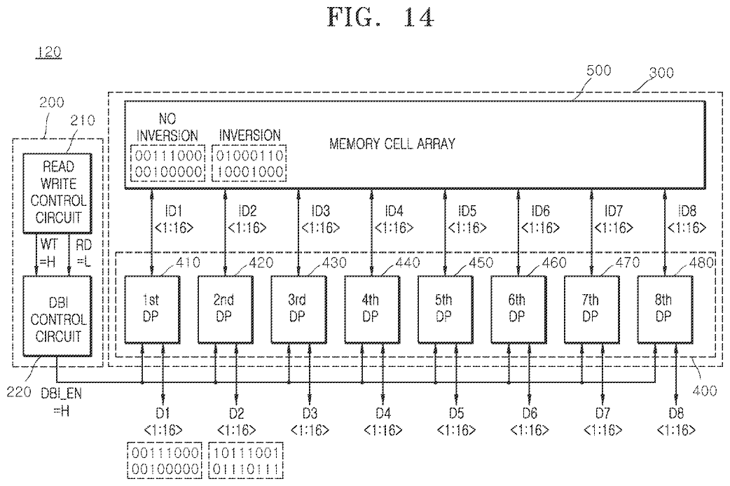

A data bus inversion operation on the first data D1<1:16> and the second data D2<1:16> in the write operation of the electronic device 100 in accordance with the embodiment of the disclosure will be described with reference to FIG. 14 by taking an example in which the number of bits in the second data D2<1:16> that have the predetermined logic level (a logic high level) is equal to or greater than the preset number.

The controller 110 may output the first data D1<1:16> of “0011100000100000” and the second data D2<1:16> of “1011100101110111” to perform the write operation. The first data D1<1:16> includes four logic high levels, and the second data D2<1:16> includes 11 logic high levels.

The read write control circuit 210 may generate the write signal WT that is enabled to perform the write operation under the control of the controller 110.

The data inversion control circuit 220 may generate the data inversion enable signal DBI_EN that is enabled to perform the data bus inversion operation as the write signal WT is enabled.

The first data processing circuit 410 may detect the number of bits in the first data D1<1:16> that have the predetermined logic level (a logic high level), by the data inversion enable signal DBI_EN that is enabled to a logic high level in the write operation. Since the number (four) of predetermined logic levels (logic high levels) among bits that are included in the first data D1<1:16> is less than the preset number, the first data processing circuit 410 may generate the first internal data ID1<1:16> by non-inverting (NO INVERSION) logic levels of the first data D1<1:16>. At this time, the first internal data ID1<1:16> may be generated as “0011100000100000.”

The second data processing circuit 420 may detect the number of bits in the second data D2<1:16> that have the predetermined logic level (a logic high level), by the data inversion enable signal DBI_EN that is enabled to a logic high level in the write operation. Since the number (11) of predetermined logic levels (logic high levels) among bits that are included in the second data D2<1:16> is equal to or greater than the preset number, the second data processing circuit 420 may generate the second internal data ID2<1:16> by inverting (INVERSION) logic levels of the second data D2<1:16>. At this time, the second internal data ID2<1:16> may be generated as “0100011010001000.”

The memory cell array 500 may store the first internal data ID1<1:16> of “0011100000100000” and the second internal data ID2<1:16> of “0100011010001000.”

As is apparent from the above description, in the electronic device in accordance with the embodiment of the disclosure, a semiconductor device may internally perform a data bus inversion operation without the control of a controller. In addition, in the electronic device in accordance with the embodiment of the disclosure, a circuit for detecting a bit with a predetermined logic level, included in data, in order to perform a data bus inversion operation may be disposed not on an external transmission line, but inside a memory region. Thus, the number of transmission lines may be reduced, and current consumption and area may be reduced.

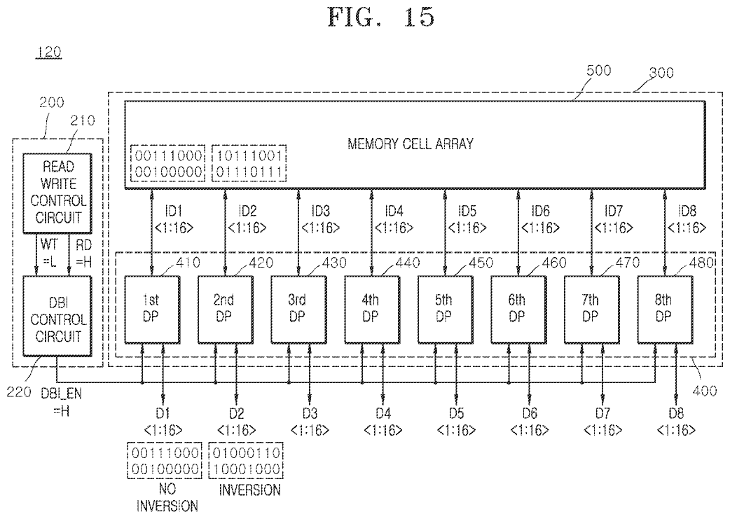

A data bus inversion operation on the first internal data ID1<1:16> and the second internal data ID2<1:16> in the read operation of the electronic device 100 in accordance with the embodiment of the disclosure will be described with reference to FIG. 15 by taking an example in which the number of bits in the second internal data ID2<1:16> that have the predetermined logic level (a logic high level) is equal to or greater than the preset number.

The read write control circuit 210 may generate the read signal RD that is enabled to perform the read operation under the control of the controller 110.

The data inversion control circuit 220 may generate the data inversion enable signal DBI_EN that is enabled to perform the data bus inversion operation as the read signal RD is enabled.

The memory cell array 500 may output the first internal data ID1<1:16> of “0011100000100000” and the second internal data ID2<1:16> of “1011100101110111” stored therein.

The first data processing circuit 410 may detect the number of bits in the first internal data ID1<1:16> that have the predetermined logic level (a logic high level), by the data inversion enable signal DBI_EN that is enabled to a logic high level in the read operation. Since the number (four) of predetermined logic levels (logic high levels) among bits that are included in the first internal data ID1<1:16> is less than the preset number, the first data processing circuit 410 may generate the first data D1<1:16> by non-inverting (NO INVERSION) logic levels of the first internal data ID1<1:16>. At this time, the first data D1<1:16> may be generated as “0011100000100000.” The first data processing circuit 410 may output the first data D1<1:16> to the controller 110 through the first transmission line L11.

The second data processing circuit 420 may detect the number of bits in the second internal data ID2<1:16> that have the predetermined logic level (a logic high level), by the data inversion enable signal DBI_EN that enabled to a logic high level in the read operation. Since the number (11) of predetermined logic levels (logic high levels) among bits that are included in the second internal data ID2<1:16> is equal to or greater than the preset number, the second data processing circuit 420 may generate the second data D2<1:16> by inverting (INVERSION) logic levels of the second internal data ID2<1:16>. At this time, the second data D2<1:16> may be generated as “0100011010001000.” The second data processing circuit 420 may output the second data D2<1:16> to the controller 110 through the second transmission line L12.

As is apparent from the above description, in the electronic device in accordance with the embodiment of the disclosure, a semiconductor device may internally perform a data bus inversion operation without the control of a controller. In addition, in the electronic device in accordance with the embodiment of the disclosure, a circuit for detecting a bit with a predetermined logic level, included in data, in order to perform a data bus inversion operation may be disposed not on an external transmission line, but inside a memory region. Thus, the number of transmission lines may be reduced, and current consumption and area may be reduced,

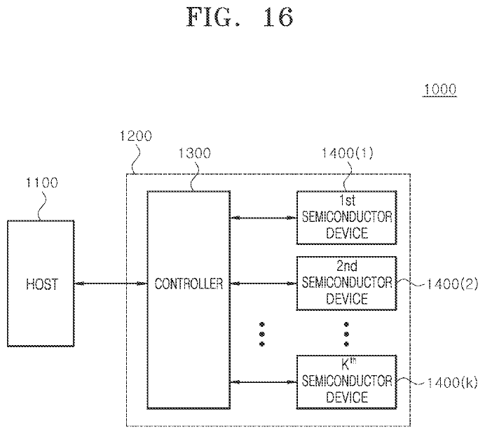

FIG. 16 is a block diagram illustrating a representation of an example of the configuration of an electronic system 1000 in accordance with an embodiment of the disclosure. As illustrated in FIG. 16, the electronic system 1000 may include a host 1100 and a semiconductor system 1200.

The host 1100 and the semiconductor system 1200 may transmit signals to each other by using an interface protocol. Examples of the interface protocol used between the host 1100 and the semiconductor system 1200 may include MMC (multimedia card), ESDI (enhanced small disk interface), IDE (integrated drive electronics), PCI-E (peripheral component interconnect-express), ATA (advanced technology attachment), SATA (serial ATA), PATA (parallel ATA), SAS (serial attached SCSI), and USB (universal serial bus).

The semiconductor system 1200 may include a controller 1300 and semiconductor devices 1400(k:1). The controller 1300 may control each of the semiconductor devices 1400(k:1) to perform a write operation and a read operation. Each of the semiconductor devices 1400(k:1) may internally perform a data bus inversion operation without the control of the controller 1300. In addition, each of the semiconductor devices 1400(k:1) has a circuit for detecting a bit with a predetermined logic level, included in data, in order to perform a data bus inversion operation, not in an interface protocol but in a memory region. Thus, the number of interface protocols may be reduced, and thus, current consumption and area may be reduced.

The controller 1300 may be implemented by the controller 110 illustrated in FIG. 1. Each of the semiconductor devices 1400(k:1) may be implemented by the semiconductor device 120 illustrated in FIGS. 1 and 2. According to an embodiment, the semiconductor device 120 may be realized by one among a DRAM (dynamic random access memory), a PRAM (phase change random access memory), an RRAM (resistive random access memory), an MRAM (magnetic random access memory) and an FRAM (ferroelectric random access memory).

While various embodiments have been described above, it will be understood to those skilled in the art that the embodiments described are by way of example only. Accordingly, the electronic device for performing a data bus inversion operation described herein should not be limited based on the described embodiments.

What is claimed is:

1. An electronic device comprising:
a first data processing circuit configured to detect logic levels of bits that are included in a first data and generate a first internal data by inverting the logic levels of the first data when a number of bits in the first data that have a predetermined logic level is equal to or greater than a preset number; and
a second data processing circuit configured to detect logic levels of bits that are included in a second data and generate a second internal data by inverting the logic levels of the second data when a number of bits in the second data that have the predetermined logic level is equal to or greater than the preset number.

2. The electronic device according to claim 1, wherein
the first data processing circuit generates the first internal data by non-inverting the logic levels of the first data when the number of bits in the first data that have the predetermined logic level is less than the preset number, and
the second data processing circuit generates the second internal data by non-inverting the logic levels of the second data when the number of bits in the second data that have the predetermined logic level is less than the preset number.

3. The electronic device according to claim 1, wherein the first and second data processing circuits are positioned in a memory region with a memory cell array in which the first and second internal data are stored.

4. The electronic device according to claim 1, wherein
the first data processing circuit generates the first internal data by aligning and parallelizing the first data that is input in series, and
the second data processing circuit generates the second internal data by aligning and parallelizing the second data that is input in series.

5. The electronic device according to claim 1, wherein the first data processing circuit comprises:
a first data buffer configured to generate a first transfer data by receiving the first data;
a first alignment circuit configured to generate a first alignment data by aligning and parallelizing the first transfer data that is input in series;
a first data detection circuit configured to generate a first detection signal by detecting the number of bits in the first alignment data that have the predetermined logic level; and
a first data transformation circuit configured to generate the first internal data by inverting or non-inverting the first alignment data based on the first detection signal.

6. The electronic device according to claim 5, wherein the first data detection circuit comprises:
a first detection circuit configured to generate a first group of a first pre-detection signal by detecting logic levels of a first group of bits that are included in the first alignment data when a data inversion enable signal is enabled;
a second detection circuit configured to generate a second group of the first pre-detection signal by detecting logic levels of a second group of bits that are included in the first alignment data when the data inversion enable signal is enabled; and
a first detection signal generation circuit configured to generate the first detection signal by detecting logic levels of the first and second groups of the first pre-detection signal.

7. The electronic device according to claim 1, wherein the second data processing circuit comprises:
a second data buffer configured to generate a second transfer data by receiving the second data;
a second alignment circuit configured to generate a second alignment data by aligning and parallelizing the second transfer data that is input in series;
a second data detection circuit configured to generate a second detection signal by detecting the number of bits in the second alignment data that have the predetermined logic level; and
a second data transformation circuit configured to generate the second internal data by inverting or non-inverting the second alignment data based on the second detection signal.

8. The electronic device according to claim 7, wherein the second data detection circuit comprises:
a third detection circuit configured to generate a first group of a second pre-detection signal by detecting logic levels of a first group of bits that are included in the second alignment data when a data inversion enable signal is enabled;
a fourth detection circuit configured to generate a second group of the second pre-detection signal by detecting logic levels of a second group of bits that are included in the second alignment data when the data inversion enable signal is enabled; and
a second detection signal generation circuit configured to generate the second detection signal by detecting logic levels of the first and second groups of the second pre-detection signal.

9. An electronic device comprising:
a control circuit positioned in a peripheral region, and configured to generate a data inversion enable signal that is enabled to control a data bus inversion operation on data and an internal data in a write operation and a read operation; and
a data processing circuit, positioned in a memory region, configured to store the internal data that is generated by inverting or non-inverting logic levels of the data based on a result of detecting the number of bits in the data that is input from an exterior that have a predetermined logic level when the data inversion enable signal is enabled in the write operation, configured to generate the data by inverting or non-inverting logic levels of the internal data based on a result of detecting the number of bits in the internal data that is stored in an interior that have the predetermined logic level when the data inversion enable signal is enabled in the read operation, and configured to output the data to the exterior.

10. The electronic device according to claim 9, wherein
the peripheral region is a region in which circuits for controlling an operation of the electronic device are positioned, and
the memory region is a region with a memory cell array in which the internal data is stored.

11. The electronic device according to claim 9, wherein the control circuit comprises:
a read write control circuit configured to generate a write signal that is enabled to enter the write operation and a read signal that is enabled to enter the read operation; and
a data inversion control circuit configured to generate the data inversion enable signal that is enabled when any one of the write signal and the read signal is enabled.

12. The electronic device according to claim 9, wherein the data processing circuit comprises:
a first data processing circuit configured to, in the write operation, detect logic levels of bits that are included in first data, and generate first internal data by inverting the logic levels of the first data when the number of bits in the first data that have the predetermined logic level is equal to or greater than a preset number; and
a second data processing circuit configured to, in the write operation, detect logic levels of bits that are included in second data, and generate second internal data by inverting the logic levels of the second data when the number of bits in the second data that have the predetermined logic level is equal to or greater than the preset number.

13. The electronic device according to claim 12, wherein
the first data processing circuit generates the first internal data by non-inverting the logic levels of the first data when the number of bits in the first data that have the predetermined logic level is less than the preset number, and
the second data processing circuit generates the second internal data by non-inverting the logic levels of the second data when the number of bits in the second data that have the predetermined logic level is less than the preset number.

14. The electronic device according to claim 9, wherein the data processing circuit comprises:
a first data processing circuit configured to, in the read operation, detect logic levels of bits that are included in first internal data and generate first data by inverting the logic levels of the first internal data when the number of bits in the first internal data that have the predetermined logic level is equal to or greater than a preset number; and
a second data processing circuit configured to, in the read operation, detect logic levels of bits that are included in second internal data and generate second data by inverting the logic levels of the second internal data when the number of bits in the second internal data that have the predetermined logic level is equal to or greater than the preset number.

15. The electronic device according to claim 14, wherein
the first data processing circuit generates the first data by non-inverting the logic levels of the first internal data when the number of bits in the first internal data that have the predetermined logic level is less than the preset number, and
the second data processing circuit generates the second data by non-inverting the logic levels of the second internal data when the number of bits in the second internal data that have the predetermined logic level is less than the preset number.

16. An electronic device comprising:
a controller configured to output a first data through a first transmission line, and output a second data through a second transmission line; and
a semiconductor device configured to store first internal data that is generated by inverting logic levels of the first data when the number of bits in the first data that have a predetermined logic level is equal to or greater than a preset number, and store second internal data that is generated by inverting logic levels of the second data when the number of bits in the second data that have the predetermined logic level is equal to or greater than a preset number.

17. The electronic device according to claim 16, wherein the semiconductor device comprises:
a first data processing circuit, positioned between the first transmission line and a memory cell array, configured to detect logic levels of bits that are included in the first data and configured to generate the first internal data by inverting the logic levels of the first data when the number of bits in the first data that have the predetermined logic level is equal to or greater than the preset number; and
a second data processing circuit, positioned between the second transmission line and the memory cell array, configured to detect logic levels of bits that are included in the second data and configured to generate the second internal data by inverting the logic levels of the second data when the number of bits in the second data that have the predetermined logic level is equal to or greater than the preset number.

18. The electronic device according to claim 17, wherein
the first data processing circuit generates the first internal data by non-inverting the logic levels of the first data when the number of bits in the first data that have the predetermined logic level is less than the preset number, and
the second data processing circuit generates the second internal data by non-inverting the logic levels of the second data when the number of bits in the second data that have the predetermined logic level is less than the preset number.

19. The electronic device according to claim 17, wherein
the first data processing circuit generates the first internal data by aligning and parallelizing the first data that is input in series, and
the second data processing circuit generates the second internal data by aligning and parallelizing the second data that is input in series.

20. The electronic device according to claim 17, wherein the first data processing circuit comprises:
a first data buffer configured to generate a first transfer data by receiving the first data;
a first alignment circuit configured to generate a first alignment data by aligning and parallelizing the first transfer data that is input in series;
a first data detection circuit configured to generate a first detection signal by detecting the number of bits in the first alignment data that have the predetermined logic level; and
a first data transformation circuit configured to generate the first internal data by inverting or non-inverting the first alignment data based on the first detection signal.

21. The electronic device according to claim 20, wherein the first data detection circuit comprises:
a first detection circuit configured to generate a first group of a first pre-detection signal by detecting logic levels of a first group of bits that are included in the first alignment data when a data inversion enable signal is enabled;
a second detection circuit configured to generate a second group of the first pre-detection signal by detecting logic levels of a second group of bits that are included in the first alignment data when the data inversion enable signal is enabled; and
a first detection signal generation circuit configured to generate the first detection signal by detecting logic levels of the first and second groups of the first pre-detection signal.

22. The electronic device according to claim 17, wherein the second data processing circuit comprises:
a second data buffer configured to generate a second transfer data by receiving the second data;
a second alignment circuit configured to generate a second alignment data by aligning and parallelizing the second transfer data that is input in series;
a second data detection circuit configured to generate a second detection signal by detecting the number of bits in the second alignment data that have the predetermined logic level; and
a second data transformation circuit configured to generate the second internal data by inverting or non-inverting the second alignment data based on the second detection signal.

23. The electronic device according to claim 22, wherein the second data detection circuit comprises:
a third detection circuit configured to generate a first group of a second pre-detection signal by detecting logic levels of a first group of bits that are included in the second alignment data when a data inversion enable signal is enabled;
a fourth detection circuit configured to generate a second group of the second pre-detection signal by detecting logic levels of a second group of bits that are included in the second alignment data when the data inversion enable signal is enabled; and
a second detection signal generation circuit configured to generate the second detection signal by detecting logic levels of the first and second groups of the second pre-detection signal.
